(19) United States
(12) Patent Application Publication
(10) Pub. No.: US 2024/0304477 A1
(43) Pub. Date: Sep. 12, 2024

(54) SYSTEMS AND METHODS FOR MONITORING OF A CONTROLLED ENVIRONMENT IN A SUBSTRATE PROCESSING SYSTEM

(71) Applicant: ASM IP Holding B.V., Almere (NL)

(72) Inventors: Gido van der Star, Den Haag (NL); Bert Jongbloed, Oud-Heverlee (BE)

(21) Appl. No.: 18/595,668

(22) Filed: Mar. 5, 2024

Related U.S. Application Data
(60) Provisional application No. 63/489,337, filed on Mar. 9, 2023.

(51) Int. Cl. H01L 21/67; H01L 21/673; H01L 21/677

(52) U.S. Cl. CPC H01L 21/67265; H01L 21/67389; H01L 21/6773

(57) ABSTRACT

Aspects of the disclosure relate to a substrate processing system having a controlled environment comprising one or more FOUPs configured to hold one or more substrates, a substrate processing chamber configured to process the substrate(s), a substrate handling and transporting system configured to receive the FOUP(s) and transfer the substrate(s) to and from the substrate processing chamber, an environmental sensor configured to measure one or more environmental parameters of the substrate handling and transporting system, and a controller communicatively coupled to the environmental sensor configured to track one or more positions of the substrate(s) within the substrate handling and transporting system, determine one or more environmental parameters of the substrate handling and transporting system, determine whether the environmental parameter(s) are within threshold limits at the one or more position of the substrate(s), and indicate an alert if the environmental parameter(s) are determined to not be within the threshold limits.

### CROSS-REFERENCE TO RELATED APPLICATION(S)

This Application claims the benefit of U.S. Provisional Application No. 63/489,337 filed on Mar. 9, 2023, the entire contents of which are incorporated herein by reference.

### FIELD OF INVENTION

The present disclosure generally relates to the field of semiconductor substrate processing technology, and more particularly to systems and methods for monitoring of a controlled environment within a substrate processing system.

### BACKGROUND OF THE DISCLOSURE

Substrate processing systems are commonly used for batch processing semiconductor substrates such as substrates during several fabrication stages of integrated circuits. For example, vertical processing furnaces or reactors may be used for oxidation, diffusion, annealing, chemical vapor deposition (CVD) and atomic layer deposition (ALD).

With semiconductors and semiconductor manufacturing processes becoming more advanced, there is a demand for higher substrate quality. Particle contamination can, however, severely compromise the substrate quality; for example, exposure to oxygen can cause native oxide growth on the surface of silicon substrates as well as promote the growth of organic contaminants. Contamination may occur during handling and transporting of substrate. Moreover, substrates are sensitive to various changes in the environment, such as humidity, temperature, incident radiation, vibration and so on.

To avoid contamination during transport, substrates are typically kept in a Front Opening Unified Pod (FOUP). FOUPs generally consists of a specialized enclosure designed to provide a controlled environment for the substrates. However, existing handling and transportation processes do not provide for a means for tracking the environment inside the FOUPs during transporting or between processing stages (“inline”) and instead only measure environmental factors when FOUPs are taken out of processing (“offline”). This may allow unaddressed environmental problems that can contaminate the reactor when the FOUP is unloaded, for example, if the FOUP is malfunctioning or damaged.

Monitoring of processing conditions inside the processing or reaction chamber of a reactor is common practice. However, the actual time spent processing the substrates inside the processing chamber constitutes only a small portion of the entire substrate handling process. In fact, most of the handling time is used to transfer the substrates from the FOUP to the processing chamber and back through various substrate handling and transporting modules.

There is currently little to no monitoring of environmental conditions outside of the processing chamber which delays the response to potential contamination or other environmental problems. Therefore, a need exists for an improved method and system for monitoring the environment of a substrate in a semiconductor processing system.

### SUMMARY OF THE DISCLOSURE

The present disclosure generally relates to the field of semiconductor processing technology, and more particularly to monitoring the environment of a substrate such as a wafer in a substrate processing system.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In a typical substrate processing system, there is currently little to no monitoring of environmental conditions outside of the processing chamber. In some cases, however, substrates are stored within a storage module such as a rack for longer than they are within the processing chamber. Existing systems are not able to identify environmental problems between the various substrate handling and transporting modules, which increases the risk of damage to substrates if a problem occurs. Therefore, a quick identification and correction of environmental problems is key for improving the quality and efficiency of substrate processing system as a whole.

A first overview of various aspects of the technology of the present disclosure is given hereinbelow, after which specific embodiments will be described in more detail. This overview is meant to aid the reader in understanding the technological concepts more quickly, but it is not meant to identify the most important or essential features thereof, nor is it meant to limit the scope of the present disclosure, which is limited only by the claims.

An aspect of the present disclosure relates to a method for monitoring of a controlled environment within a substrate handling and transporting system configured to receive one or more front opening universal pods (FOUPs) holding one or more substrates and to transfer the one or more substrates to and from a substrate processing chamber; the method comprising the steps of:
tracking one or more positions of the one or more substrates within the substrate handling and transporting system;
determining one or more environmental parameters of the substrate handling and transporting system at the one or more positions of the one or more substrates;
determining whether the one or more environmental parameters are within threshold limits and indicating an alert if the one or more environmental parameters are determined to not be within the threshold limits.

In some embodiments the substrate handling and transporting system comprises at least one of a FOUP handling module, a FOUP transport module, a substrate handling module, a substrate storage module, and a substrate transport module.

In some embodiments the positions of the one or more substrates are tracked based on an operation performed by the substrate handling and transporting system, wherein the operation comprises at least one of a loading/unloading of the one or more substrates into/from the one or more FOUPs, a transferring of the one or more substrates within the substrate handling and transporting system, a storing of the one or more substrates, a loading/unloading of the one or more substrates into/from the substrate processing chamber, and/or a cooling of the one or more substrates.

In some embodiments the method comprises determining one or more environmental parameters of the substrate handling and transporting system at one or more future positions of the one or more substrates; and determining whether said one or more environmental parameters are within threshold limits.

In some embodiments the method comprises stopping the transfer of the one or more substrates within the substrate handling and transporting system if the one or more environmental parameters are determined to not be within the threshold limits.

In some embodiments the method comprises stopping an operation by the substrate handling and transporting system if the one or more environmental parameters are determined to not be within the threshold limits wherein the operation comprises at least one of stopping an unloading of the one or more substrates from the one or more FOUPs, stopping a transferring of the one or more substrates within the substrate handling and transporting system, stopping a loading of the one or more substrates into the substrate processing chamber, stopping an unloading of the one or more substrates from the substrate processing chamber, and stopping a loading of the one or more substrates into one or more FOUPs.

In some embodiments the method comprises determining one or more processing conditions based on the one or more environmental parameters, and processing the one or more substrates within the processing chamber based on said processing conditions.

In some embodiments the method comprises correcting the environment if the one or more environmental parameters are determined to not be within the threshold levels, wherein the correcting comprises at least one of purging, sealing, flushing, renewing gas, reducing radiation, reducing vibration, removing particles, changing humidity, and/or changing a temperature.

In some embodiments the one or more environmental parameters of the substrate handling and transporting system are measured with one or more environmental sensors disposed within the substrate processing system.

In some embodiments the one or more environmental parameters of a module of the substrate handling and transporting system are calculated based on one or more environmental parameters measured with one or more environmental sensors disposed within another module of the substrate processing system that is environmentally coupled.

In some embodiments the method comprises determining one or more environmental parameters in the one or more FOUPs.

In some embodiments the one or more environmental parameters of the FOUP are measured with one or more environmental sensors disposed within the FOUP.

In some embodiments the one or more environmental parameters of the FOUP are calculated based on one or more environmental parameters measured with one or more environmental sensors disposed within a module of the substrate handling and transporting system that is configured to handle, open or close the FOUP.

In some embodiments the one or more environmental parameters comprise at least one of a particle concentration, chemical composition, humidity, temperature, vibration, and/or incident radiation.

In some embodiments the chemical concentration comprises an oxygen concentration.

In some embodiments the one or more environmental parameters are determined to be within threshold limits in real time.

In some embodiments the one or more environmental parameters are determined to be within threshold limits at particular times based on an operation performed by the substrate processing system, wherein the operation comprises at least one of a loading/unloading of the one or more substrates into/from the one or more FOUPs, a transferring of the one or more substrates within the substrate handling and transporting system, a storing of the one or more substrates, a loading/unloading of the one or more substrates into/from the substrate processing chamber, and/or a cooling of the one or more substrates.

In some embodiments the method comprises logging of the one or more environmental parameters for the one or more substrates at one or more points in time and at one or more substrate positions.

In some embodiments the method comprises determining one or more environmental parameters in the substrate processing chamber.

In some embodiments the one or more environmental parameters of the substrate processing chamber are measured with one or more environmental sensors disposed within the substrate processing chamber.

In some embodiments the one or more environmental parameters of the substrate processing chamber are calculated based on one or more environmental parameters measured with one or more environmental sensors disposed within a module of the substrate handling and transporting system that is configured to handle, open and/or close the substrate processing chamber.

Another aspect of the present disclosure relates to a substrate processing system having a controlled environment, the system comprising:
one or more FOUPs configured to hold one or more substrates;
a processing chamber configured to process the one or more substrates;
a substrate handling and transporting system configured to receive the one or more FOUPs and transfer the one or more substrates to and from the substrate processing chamber;
an environmental sensor means configured to measure one or more environmental parameters of the substrate handling and transporting system; and,
a controller communicatively coupled to the environmental sensor means, that is configured to track one or more positions of the one or more substrates within the substrate handling and transporting system, determine one or more environmental parameters of the substrate handling and transporting system, determine whether the one or more environmental parameters are within threshold limits at the one or more position of the one or more substrates, and indicate an alert if the one or more environmental parameters are determined to not be within the threshold limits.

In some embodiments the substrate handling and transporting system comprises at least one of a FOUP handling module, a FOUP transport module, a substrate handling module, a substrate storage module, and a substrate transport module.

In some embodiments the controller is configured to track the positions of the one or more substrates based on an operation performed by the substrate processing system, wherein the operation comprises at least one of a loading/unloading of the one or more substrates into/from the one or more FOUPs, a transferring of the one or more substrates within the substrate handling and transporting system, a storing of the one or more substrates, a loading/unloading of the one or more substrates into/from the substrate processing chamber, and/or a cooling of the one or more substrate.

In some embodiments the controller is configured to issue an instruction to the handling system to stop the transfer of the one or more substrates within the substrate processing system if the one or more environmental parameters are determined to not be within the threshold limits.

In some embodiments the controller is configured to determine one or more processing conditions based on the one or more environmental parameters, and to issue an instruction to the processing chamber to process the one or more substrates based on said processing conditions.

In some embodiments the substrate processing system comprises one or more environmental support devices configured to support the controlled environment of the substrate processing system, and wherein the controller is configured to issue an instruction to the one or more environmental support devices to correct the environment if the one or more environmental parameters are determined to not be within the threshold levels; wherein the correction comprises at least one of purging, scaling, flushing, renewing gas, reducing radiation, reducing vibration, removing particles, changing humidity, and/or changing a temperature.

In some embodiments the environmental sensor means comprises one or more environmental sensors disposed within the handling system, and wherein the controller is configured to determine the one or more environmental parameters of the handling system based on measurement from said environmental sensors.

In some embodiments the environmental sensor means comprises one or more environmental sensors disposed within a module of the handling system, and wherein the controller is configured to determine the one or more environmental parameters of another module of the handling system that is environmentally coupled based on measurement from said environmental sensors.

In some embodiments the environmental sensor means comprises one or more environmental sensors disposed within the FOUP, and wherein the controller is configured to determine the one or more environmental parameters of the FOUP system based on measurement from said environmental sensors.

In some embodiments the environmental sensor means comprises one or more environmental sensors disposed within a module of the handling system that is configured to handle, open or close the FOUP, and wherein the controller is configured to determine the one or more environmental parameters of the FOUP based on measurement from said environmental sensors.

In some embodiments the environmental sensor means is configured to measure at least one of a particle concentration, chemical composition, humidity, temperature, vibration, and/or incident radiation.

In some embodiments the controller is configured to determine whether the one or more environmental parameters are within threshold limits in real time.

In some embodiments the controller is configured to determine whether the one or more environmental parameters are within threshold limits at particular times based on an operation performed by the substrate processing system, wherein the operation comprises at least one of a loading/unloading of the one or more substrates into/from the one or more FOUPs, a transferring of the one or more substrates within the substrate handling and transporting system, a storing of the one or more substrates, a loading/unloading of the one or more substrates into/from the substrate processing chamber, and/or a cooling of the one or more substrate.

In some embodiments the controller is configured to log the one or more environmental parameters for the one or more substrates at one or more points in time and at one or more substrate positions.

In some embodiments the environmental sensor means further comprises one or more environmental sensors disposed within the substrate processing chamber, and wherein the controller is configured to determine one or more environmental parameters of the substrate processing chamber based on measurement from said environmental sensors.

In some embodiments the handle, open and/or close environmental sensor means comprises one or more environmental sensors disposed within a module of the substrate handling and transporting system that is configured to handle, open and/or close the substrate processing chamber, and wherein the controller is configured to determine one or more environmental parameters of the substrate processing chamber based on measurement from said environmental sensors.

Another aspect of the present disclosure relates to an apparatus for monitoring a controlled environment of a substrate handling and transporting system configured to receive one or more front opening universal pods (FOUPs) holding one or more substrates and to transfer the one or more substrates to and from a substrate processing chamber, the apparatus comprising:
an environmental sensor means configured to measure one or more environmental parameters of the substrate handling and transporting system; and,
a controller communicatively coupled to the environmental sensor means, that is configured to track one or more positions of the one or more substrates within the substrate handling and transporting system, determine one or more environmental parameters of the substrate handling and transporting system, determine whether the one or more environmental parameters are within threshold limits at the one or more position of the one or more substrates, and indicate an alert if the one or more environmental parameters are determined to not be within the threshold limits.

### BRIEF DESCRIPTION OF THE DRAWING FIGURES

The following description of the figures relate to specific embodiments of the disclosure which are merely exemplary in nature and not intended to limit the present teachings, their application or uses.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

Throughout the drawings, the corresponding reference numerals indicate the following parts and features: substrate processing system 10; substrate 11; Front Opening Unified Pod (FOUP) 20; environmental sensor 21; substrate handling and transporting system 30; environmental sensor 31; environmental support device 35; processing chamber 40; environmental sensor 41; environmental support device 45; controller 50; communications module 51; processor 55; display device 60; alert 61.

FIG. 1 is a diagram of a system for monitoring an environment of a substrate in a substrate processing system in accordance with aspects of the present disclosure.

FIG. 2 is a diagram of a system for monitoring an environment of a substrate in a FOUP in accordance with aspects of the present disclosure.

FIG. 3 is a flow diagram of a method for monitoring an environment of a substrate in a substrate processing system in accordance with aspects of the present disclosure.

### DETAILED DESCRIPTION OF EXEMPLARY EMBODIMENTS

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims.

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

The present disclosure relates to monitoring the environment of a substrate in a substrate processing system. While the present disclosure is described in terms of monitoring the environment in a vertical processing furnace or reactor by way of example, it will be appreciated that any system for processing, handling, or transporting of sensitive substrates can benefit from the present monitoring technology. For example, it can be equally advantageous to monitor the environment of a substrate in an optical lithography system, such as Extreme ultraviolet lithography, or any other system configured for processing substrates.

As previously discussed, in substrate processing system, there is currently little to no monitoring of environmental conditions outside of the processing chamber which delays the response to react to potential contamination or other environmental problems. Once the contamination of a batch of substrates has been detected, it might be necessary to interrupt the processing line to identify the cause of contamination resulting in significant production delay. Also, by the time the cause has been identified, the contamination may spread or affect another batch. In some scenarios, the stock of contaminated batch might even need to be disposed of.

The present disclosure therefore provides for methods and systems for (real-time) monitoring of the environmental conditions in the relevant parts of the substrate processing system, that is, including parts of the substrate processing line that are located outside of the processing chamber. In some cases, substrates are stored within a storage module such as a rack for longer than they are within the processing chamber. Existing systems may not be able to identify environmental problems between handling or transporting stages, which may increase the risk of damage to substrates. Therefore, the quick identification and remedy of environmental problems as provided by the embodiments presented herein can avoid damage to substrates and improve yield (reduce yield loss).

Therefore, by way of the systems and methods described herein, it is possible to improve the response to a potential contamination or an environmental problem by speeding up the response time and optionally initiating an (automated) intervention to address the cause of contamination or the environmental problem and prevent further contamination of substrates. In this way, the demands for higher substrate quality in the semiconductor field can be met.

An overview of various aspects of the technology of the present disclosure is given hereinbelow, after which specific embodiments will be described in more detail. This overview is meant to aid the reader in understanding the technological concepts more quickly, but it is not meant to identify the most important or essential features thereof, nor is it meant to limit the scope of the present disclosure. When describing specific embodiments, reference is made to the accompanying drawings, which are provided solely to aid in the understanding of the described embodiment.

An aspect of the present disclosure relates to a method for monitoring of a controlled environment within a substrate handling and transporting system configured to receive one or more front opening universal pods (FOUPs) holding one or more substrates and to transfer the one or more substrates to and from a substrate processing chamber; the method comprising the steps of:
tracking one or more positions of the one or more substrates within the substrate handling and transporting system;
determining one or more environmental parameters of the substrate handling and transporting system at the one or more positions of the one or more substrates;
determining whether the one or more environmental parameters are within threshold limits and indicating an alert if the one or more environmental parameters are determined to not be within the threshold limits.

Another aspect of the present disclosure relates relates to a substrate processing system having a controlled environment, the system comprising:
one or more FOUPs configured to hold one or more substrates;
a processing chamber configured to process the one or more substrates;
a substrate handling and transporting system configured to receive the one or more FOUPs and transfer the one or more substrates to and from the substrate processing chamber;
an environmental sensor means configured to measure one or more environmental parameters of the substrate handling and transporting system; and,
a controller communicatively coupled to the environmental sensor means, that is configured to track one or more positions of the one or more substrates within the substrate handling and transporting system, determine one or more environmental parameters of the substrate handling and transporting system, determine whether the one or more environmental parameters are within threshold limits at the one or more position of the one or more substrates, and indicate an alert if the one or more environmental parameters are determined to not be within the threshold limits.

Another aspect of the present disclosure relates relates to an apparatus for monitoring a controlled environment of a substrate handling and transporting system configured to receive one or more front opening universal pods (FOUPs) holding one or more substrates and to transfer the one or more substrates to and from a substrate processing chamber, the apparatus comprising:
an environmental sensor means configured to measure one or more environmental parameters of the substrate handling and transporting system; and,
a controller communicatively coupled to the environmental sensor means, that is configured to track one or more positions of the one or more substrates within the substrate handling and transporting system, determine one or more environmental parameters of the substrate handling and transporting system, determine whether the one or more environmental parameters are within threshold limits at the one or more position of the one or more substrates, and indicate an alert if the one or more environmental parameters are determined to not be within the threshold limits.

It is understood, based on any of the embodiments described herein, that the herein disclosed method can be performed by the herein disclosed system. That is, the hardware or software of the system can be adapted in a way that it can perform the method and any steps thereof, and vice versa, even if not explicitly described as such. As an example, the system's controller may be adapted to perform a relevant step of the method, for example, when it receives a relevant environmental parameter as input, for example, in the form of sensor data acquired by one or more environmental sensors that are disposed within the system.

Referring to FIG. 1, a diagram of a substrate processing system 10 is shown. The substrate processing system 10 comprises a substrate handling and transporting system 30, a processing chamber 40, a controller 50, and an output device 60. One or more substrates 11 can be provided to the substrate processing system 10 in a Front Opening Unified Pod (FOUP) 20. A FOUP 20 generally consists of a specialized enclosure designed to provide a controlled environment for the substrates 11 stored within. The substrate handling and transporting system 30 can accordingly comprise means for receiving and interacting with the one or more FOUPS 20, more specifically, a means for unloading the one or more substrates 11 from within said FOUP and transporting them to the processing chambers 40 for the intended processing of the one or more substrates 11, and vice versa. The relevant movement of the substrates 11 between the FOUP 20, the substrate handling and transporting system 30 and the processing chamber 40 is indicated by dashed arrows.

It is understood that the substrate handling and transporting system 30 in FIG. 1 is an abstract representation of a plurality of devices that are configured to perform all of the actions required for transferring the substrates 11 from the FOUP 20 into the processing chamber 40 and vice versa. The number of included devices can vary depending on the complexity of the loading and unloading processes, but for the sake of simplicity, the substrate handling and transporting system will be discussed below with functional modules. In some embodiments, the handling and transporting system may comprise at least one of a FOUP handling module, a FOUP transport module, a substrate handling module, a substrate storage module, and a substrate transport module. Additionally, in the present disclosure the FOUP is considered as a component of the substrate processing system. As such, any embodiment of the substrate processing system may be considered as an embodiment of the FOUP, unless stated otherwise.

An example of a substrate loading cycle of a vertical processing furnace is discussed next. This example is included to aid the reader in understanding the technological concepts more easily, but the skilled person appreciates that any system for processing, handling, and transporting of sensitive substrates can benefit from the present monitoring technology. For example, it can be equally advantageous to monitor the environment of a substrate in a lithography system.

A plurality of substrates can be provided to the system in a FOUP, which can be handled by a FOUP handling module. Advantageously, the FOUP handling module may comprise a robot arm that can automatically load the provided FOUP into a FOUP carousel or store it in a FOUP storage rack, depending on the availability. From the FOUP carrousel, the FOUP can next be placed onto a swapper that transfers it to a FOUP door opener. With the FOUP door opened, the substrates can be unloaded by a substrate handling module into a boat on a reactor carousel module, with the possible use of an intermediate substrate storage. Advantageously, the substrate handling module may comprise a robot arm that can automatically move the substrate from the FOUP into the boat. The boat loaded with substrates can then be rotated by a reactor carousel from the loading position to the reactor position so that a boat elevator can move the boat in and out of the processing chamber. After processing, the boat on the reactor carousel can be rotated back to a cool down position. After cooldown, the boat can be moved to the unload position, where the substrate handling module can perform an unloading cycle equivalently to the previously described loading cycle.

In some embodiments, the substrate handling and transporting system, more specifically the substrate transport module may comprise a substrate carrier means configured to hold the substrates during transport. For example, the substrate carrier may comprise a chuck for transporting a single substrate or wafer, a boat for transporting any number of substrate or wafers, and so on.

In some embodiments, the substrate handling and transporting system can comprise one or more environmental sensors that are operatively connected to a controller to provide sensor data thereto. As further shown in FIG. 1, the one or more environmental sensors 31 may be disposed within the substrate handling and transporting system 30, more specifically, within any of the devices or modules of said substrate handling and transporting system 30. In some embodiments, the one or more environmental sensors may be disposed within a stocker module, a FOUP handling module, a substrate handling module, a reactor carousel module and/or the reactor chamber. For example, the one or more environmental sensors may be disposed on an interior surface of the modules or device of the substrate handling and transporting system. The one or more environmental sensors may be disposed within a housing to protect the environmental sensors from being damaged during operation of the devices.

In some embodiments, the one or more environmental sensors can be configured to measure environmental parameters of the interior environment of the substrate handling and transporting system. In particular, the one or more environmental sensor may advantageously provide real time measurements of environmental parameters of the substrate handling and transporting system. Real time measurements can be provided by continuously measuring the environmental parameters. These measurements may be provided directly to a controller via a data stream, for example, via wired connection or a wireless transmitter. Alternatively or in combination, the measurements can be stored in one or more memory devices, which may be disposed in the substrate handling and transporting system.

In some embodiments, the one or more environmental sensors can be configured to measure environmental parameters of the interior environment of the substrate handling and transporting system at particular times. For example, the one or more environmental sensors may be configured to measure environmental parameters of the substrate handling and transporting system before, during and/or after a particular operation. For example, the environmental parameters can be measured before, during and/or after a loading/unloading of the one or more substrates into/from the one or more FOUPs, a transferring of the one or more substrates within the substrate handling and transporting system, a storing of the one or more substrates, a loading/unloading of the one or more substrates into/from the substrate processing chamber, and/or a cooling of the one or more substrate. In another example, the one or more environmental sensors may be configured to measure environmental parameters of the FOUP at specific time intervals. This may help to reduce the amount of power consumed by the environmental sensors and reduce load on the controller.

In some embodiments, the one or more environmental parameters can comprise at least one of a particle concentration, a chemical composition, a humidity, a temperature, a vibration, and/or an incident radiation. Accordingly, the environmental sensor means may comprise a device configured for measuring at least one of the herein discussed environmental parameters. For example, this device can be a humidity sensor, a thermometer, an accelerometer, a radiation detector, a particle detector, a chemical detector, and the like. The relevant environmental parameters are application specific. For example, for metal and metal nitrides typically low oxygen and humidity levels are needed, hence the monitoring of oxygen and humidity can be more relevant for such application. Advantageously, the chemical concentration comprises oxygen, more specifically the oxygen concentration as it is relevant for preventing native oxide growth on a silicon wafer.

The substrate processing system may be configured to support a controlled environment. Aspects or parameters of this controlled environment may include, for example, humidity, temperature, vibration, incident radiation, particle density, and chemical composition. The controlled environment may be created by one or more environmental support devices in the substrate processing system. These environmental support devices may include vents and purging systems, mechanical structures such as anti-radiation plating and coatings, anti-vibration systems, gaskets, flanges, and other sealing features, gas systems such as humidity control devices, input/output valves, and electronics to support the environmental support devices. For example, the substrate processing system may include a primarily nitrogen gas environment that helps to avoid native oxide growth on silicon substrates as well as kill organic contaminants. In some embodiments, the substrate processing system is configured to maintain a particle free nitrogen environment with a constant temperature, humidity, and minimal incident radiation and vibration. In some embodiments, the one or more environmental sensors are connected to the one or more environmental support devices.

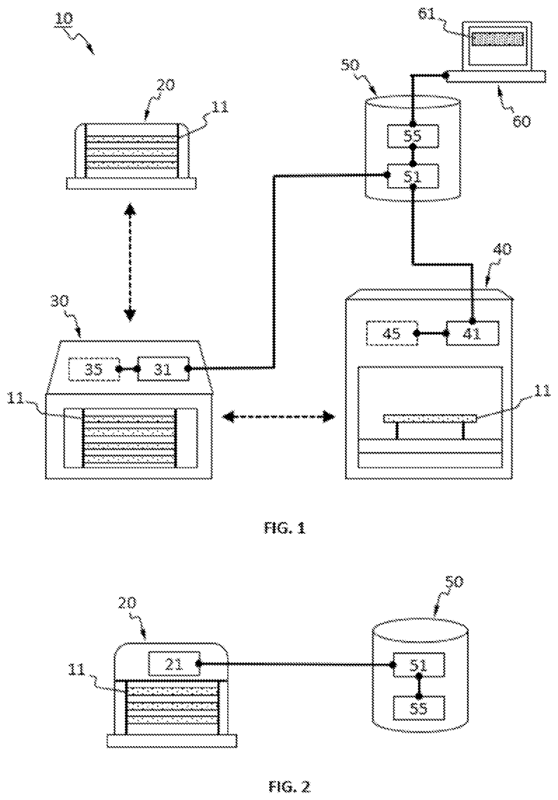

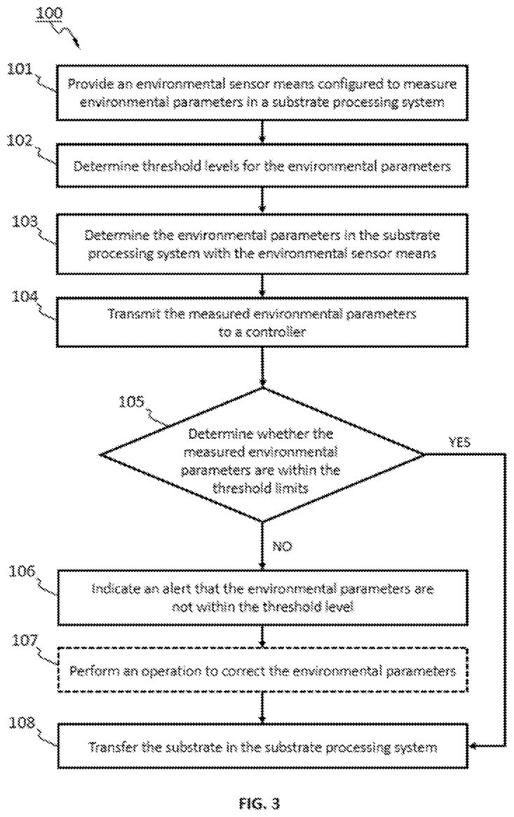

Referring to FIG. 2, it is shown that in a further embodiment, the FOUP 20 may comprise one or more environmental sensors 21 configured for determining one or more environmental parameters in said FOUP. In some embodiments, the one or more environmental sensors 21 can be configured to measure environmental parameters of the interior environment of the FOUP 20. Advantageously, the one or more environmental sensor may provide real time measurements of environmental parameters of the FOUP. Real time measurements can be provided by continuously measuring the environmental parameters. Alternatively, the one or more environmental sensor may provide measurements of environmental parameters of the FOUP at particular times. For example, the one or more environmental sensors may be configured to measure environmental parameters of the FOUP before and/or after opening and/or closing. In another example, the one or more environmental sensors may be configured to measure environmental parameters of the FOUP at specific intervals. This may help to reduce the amount of power consumed by the environmental sensors and reduce the overall complexity of the system.

In some embodiments, the FOUP may comprise a means for transmitting the environmental parameters measured by the one or more environmental sensor to the controller. In some embodiments the FOUP may comprise a wireless transmitter that is configured to wirelessly transmit the measured environmental parameters to the controller. Alternatively or in combination, the FOUP may comprise a connector for establishing a wired connection for read-out of sensor data to the controller, for example, when the FOUP is loaded into the FOUP handling module.

In some embodiments, the FOUP can comprise an enclosure configured to hold one or more substrates in a protected environment. Aspects or parameters of this protected environment may include, for example, humidity, temperature, vibration, incident radiation, particle density, and chemical composition. The substrates can be carried on a retaining element. The retaining element may be a rack, bracket, shelf, clip, framework, or other element to secure the substrates during transport and handling. The enclosure may have a generally rectangular shape with a body including a plurality of connected walls, a top, a base, and a FOUP door to allow loading and unloading of substrates. The enclosure may be made of a rigid material to protect and securely hold the substrates inside. In some embodiments, the enclosure is formed from plastic materials. One or more handles may be disposed on sides of the enclosure to handle and transport the FOUP.

In some embodiments, the one or more environmental sensors may be disposed within the FOUP, advantageously on an interior surface of the FOUP. As further shown in FIG. 2, the environmental sensor may be disposed within the enclosure, for example, on a wall or the door of the FOUP to protect the environmental sensors from being damaged during loading and unloading the FOUP. In some embodiments, the enclosure can be removable so that an operator can access the environmental sensors. In some embodiments, the one or more environmental sensors can be integrated into the housing of the FOUP. The enclosure may conform to the shape of the one or more environmental sensors. The enclosure may help to protect the one or more environmental sensors from being damaged during transfer.

Referring again to FIG. 1, the controller 50 comprises a processor 55, a memory, and a communication module 51 configured to receive sensor data from the one or more environmental sensor in any of the above embodiments. As further shown in FIG. 1, the controller 50 can receive sensor data from an environmental sensor 31 disposed within a substrate handling and transporting system 30 and/or receive sensor data from an environmental sensor 41 disposed within a processing chamber 40. As further shown in FIG. 2, the controller 50 can receive sensor data from an environmental sensor 21 disposed within a FOUP. After receiving sensor data from the one or more environmental sensors, the controller can analyse the environmental parameters to determine if the environmental parameters are within acceptable limits.

The processor of the controller may include any one or more of a microprocessor, a controller, a digital signal processor (DSP), an application specific integrated circuit (ASIC), a field-programmable gate array (FPGA), or equivalent discrete or integrated logic circuitry. In some embodiments, the controller is a computer system. The processor may be connected to the memory, transmitter, and receiver.

The memory of the controller may be a semiconductor memory such as, for example, read-only memory, a random access memory, a FRAM, or a NAND flash memory. The memory may interface with the processor and associated processors such that the processor may write to and read from the memory. In some embodiments, the memory may be configured to store the environmental measurements from the one or more environmental sensors. The memory may also be configured to store previous readings from the environmental sensors as well as threshold values for each environmental parameter. In this case, the controller may compare the environmental measurements to the thresholds to determine if the environment within the FOUP is within safe operating conditions. If this is not the case, the controller may issue an alert so that the environmental problem can be corrected.

The communications module of the controller may comprise a wireless receiver such as, for example, a Bluetooth or Wi-Fi, or any receiver via a wired connection. The receiver of the controller may be configured to receive transmissions from a transmitter coupled to the one or more environmental sensors. For example, a device or module of the substrate processing system may comprise a transmitter configured to receive measurements from the one or more environmental sensors and transmit the measurements to the controller. The communications module of the controller may further comprise a transmitter configured to send instructions to the substrate handling and transporting system, the processing chamber, or other locations.

In some embodiments, the controller can determine one or more environmental parameters from sensor data that is (directly) measured with one or more environmental sensors disposed in a part of the substrate processing system, more specifically, disposed within a device or module of the substrate processing system. For example, a first environmental sensor disposed within a stocker module can measure one or more environmental parameters of said stocker module and a second environmental sensor disposed within a substrate carousel module can then measure one or more environmental parameters of said substrate carousel module.

In some embodiments, the environmental sensor can determine one or more environmental parameters in one part or module of the substrate processing system by (indirectly) calculating said parameters based on sensor data that is measured with one or more environmental sensors disposed in another part or module of the substrate processing system. For example, if a first environmental sensor is disposed within a stocker module and a second environmental sensor is disposed within a substrate carousel module, then one or more environmental parameters for a substrate handling module disposed between said stocker module and said substrate carousel module can be calculated based on the one or more environmental parameters measured by said first and second environmental sensor, provided that a correlation can be determined between the relevant locations, for example, based on distance. The calculations may be performed by the controller when receiving the environmental parameters from one or more environmental sensors, or the calculations may be performed at particular times, for example, before and/or after a device or module performs an operation.

In some embodiments the controller can be connected to a display device for viewing environmental measurements, alerts, and instructions. The display device can be a computer monitor or other type of screen. The display device can be used to display the environmental status of the monitored devices, environmental alerts, or other information relevant to the handling of substrates. For example, the environmental alerts can serve to inform an operator of an environmental problem that has been identified such that an operation can be performed to correct the problem.

Referring yet again to FIG. 1, the processor 55 of the controller 50 can be configured to transmit an alert to the display device 60 identifying a monitored device with an environmental problem as well as the type of environmental problem that has been identified (for example, “oxygen” for oxygen contamination). The display device 60 can then display a visual alert 61 to one or more operators. In the example of FIG. 1, the display device 60 shows a simple “ALERT” message 61. In some embodiments, the visual alert can be differentiated by specific colours, shapes, icons, blinking patterns, and so on. For example, the colours of the visual alert may correspond with the problems that are identified, such as a yellow colour if the temperature is found to be higher than normal but still acceptable, and a red colour if the temperature is found to be above acceptable limits. Alternatively or in combination, the visual alert can include text such as a particular number or identification of the monitored device or substrate, as well as the problem that has been identified. For example, if the temperature of a monitored device in the substrate handling and transporting system was measured by one or more environmental sensors and determined to be above acceptable levels by the controller, the visual alert may, for example, list “HIGH TEMPERATURE” as the problem. In some embodiment, the alert may be replaced or combined with a sound alert, such as an audio notification that is generated by an audio device, such as a speaker. The display of the alert and other messages may allow an operator to quickly identify an environmental problem and respond accordingly. This may help to remedy the problem quickly and minimize harm to the substrates.

In some embodiments, the memory of the controller can be configured to store the environmental parameters measured by the one or more environmental sensors. For example, the environmental parameters for a monitored device may be stored during an entire operation, including before and after all loading or unloading stages. This may allow an operator to determine where environmental problems arise during specific processing stages, such as identifying areas or devices of a substrate handling and transporting system where one or more environmental parameters are higher than normal. In one embodiment, the memory may be configured to store environmental parameters from a number of monitored devices. These parameters may be compared to determine trends in the substrate environments. The storing and comparison of environmental parameters may also help to identify problematic areas or devices to avoid continuing damage to substrates.

In some embodiments, the memory of the controller can be configured to store the environmental parameters measured by the one or more environmental sensors. For example, the environmental parameters for a monitored device may be stored during an entire operation, including before and after all loading or unloading stages. This may allow an operator to determine where environmental problems arise during specific processing stages, such as identifying areas or devices of a substrate handling and transporting system where one or more environmental parameters are higher than normal. In one embodiment, the memory may be configured to store environmental parameters from a number of monitored devices. These parameters may be compared to determine trends in the substrate environments. The storing and comparison of environmental parameters may also help to identify problematic areas or devices to avoid continuing damage to substrates.

In some embodiments, the controller can track a (general) position of one or more substrates within the substrate processing system. For example, the substrate position can indicate that the substrate is inside a specific module or device of the substrate processing system, which can include a FOUP handling module, a FOUP transport module, a substrate handling module, a substrate storage module, and a substrate transport module. Alternatively or in combination, the substrate position can indicate that the substrate is being transferred to a specific module or device.

In some embodiments, the controller can track a (specific) position of one or more substrates within a device or module of the substrate processing system. For example, the substrate position can indicate the position of a tracked substrate inside a specific module or device relative to other substrates. This position may be determined based on the loading/unloading sequence of the substrates. For example, if the controller receives information that a tracked substrate is the first substrate to be loaded into a FOUP, it can determine that said substrate is at the bottom of said FOUP.

In some embodiments, the controller can track the positions of one or more substrates based on an operation performed by the substrate processing system. The substrate position will typically not change until an operation is performed. For example, the substrate position can change before, during and/or after a loading/unloading of the one or more substrates into/from the one or more FOUPs, a transferring of the one or more substrates within the substrate handling and transporting system, a storing of the one or more substrates, a loading/unloading of the one or more substrates into/from the substrate processing chamber, and/or a cooling of the one or more substrate. Hence, the controller can update the position of the substrate at particular times whenever an operation is performed by one or more devices of the substrate processing system. This may help to reduce the amount of power consumed by the controller and reduce the overall complexity of the system.

In some embodiments, the controller can determine whether the one or more environmental parameters are within a threshold limit is performed for an individual substrate or for a group of substrates. The environmental parameters may vary within a device or module of the substrate processing system. For example, the topmost shelf of a stocker module can have a different temperature than the bottommost shelf of the same stocker module; therefore, the controller can determine that the environmental parameters for the substrates in stored in the topmost shelf can be above the threshold limit while the the environmental parameters for the substrates in stored in the bottommost shelf can be within the threshold limit still.

In some embodiments, the controller can log the one or more environmental parameters for the one or more substrates at one or more points in time and substrate positions. The environment of a substrate can change whenever it is transferred from one device or module of the substrate processing system to another device or module, which can impact the overall quality of the substrate. Advantageously, the controller can create a processing log for the substrate including the determined environmental parameters that the substrate was exposed to at the one one or more points in time and substrate positions. The processing log can be afterwards reviewed to determine the substrate production quality. This review can be performed manually by an operator, or can be reviewed by an automated system, for example, by implementing machine learning technology.

In some embodiments, the controller can also be configured to send one or more instructions to the devices or modules of the substrate processing system if the measured environmental parameters are not within acceptable limits. For example, the controller may be operatively coupled to devices or modules of the substrate handling and transporting system to minimize the effects of the environmental problem and and optionally correct the problem. Advantageously, the response can be fully automated for faster response time to avoid damage to substrates. Alternatively, the response can be semi-automated, for example, by requesting the confirmation of an operator to activate the relevant environmental support device. Semi-automated system may be necessary to ensure safety of nearby operators or risk damaging sensitive objects.

In some embodiments, the controller can be configured to send one or more instructions to the substrate handling and transporting system to stop or abort the transfer of the one or more substrates within the substrate processing system if the one or more environmental parameters are determined to not be within the threshold limits. For example, if one or more environmental sensors disposed within a stocker module send measurements to the controller that show that the environmental parameters are above safe operating limits, the controller may abort a transfer of substrates to or from said stocker module. In another example, if one or more environmental sensors within a FOUP send measurements to the controller that show that the environmental parameters are above safe operating limits, the controller may abort an opening or closing of the FOUP, or abort a transfer of substrates into or from the FOUP.

In some embodiments, the controller can be configured to determine one or more processing conditions based on the one or more environmental parameters and instruct the processing chamber to process the one or more substrates based on said processing conditions. In this way, the processing conditions in the processing chamber can be adjusted based on the environmental history of the substrates. For example, if the controller determines that the substrates were exposed to an oxygen concentration that is above safe operating limits, the processing chamber can be instructed to perform a pre-baking step to remove native oxide growth from the substrate surface. On the other hand, if the controller determines that the substrates that the oxygen concentration is within safe operating limits, this pre-baking step can be skipped by the processing chamber.

As further shown in FIG. 1, the controller 50 may be configured to control one or more environmental support devices in the substrate processing system 10 to control the environment within the substrate processing system, more specifically, one or more environmental support devices 31 in the substrate handling and transporting system 30 and/or one or more environmental support devices 41 in the processing chamber 40. This control may include adjusting the pressure, humidity, temperature, and/or chemical composition in the substrate processing system 10, more specifically, in the substrate handling and transporting system 30 and/or the processing chamber 40. For example, if an environmental sensors 31 of a substrate handling and transporting system 30 identifies the presence of oxygen above a threshold level within any of the devices or modules, in response, the controller may activate a purging system 35 to flush out the contaminants. This may allow the substrate handling and transporting system 30 to correct an environmental problem while the production line is active and without requiring the substrate processing system to be moved offline.

FIG. 3 is a flow diagram of a method 100 for monitoring an environment of a substrate in accordance with aspects of the present disclosure. It is understood that additional steps can be provided before, during, and after the steps of the method, and that some of the steps described can be replaced or eliminated for other implementations of the method.

In the shown embodiment, the method 100 begins at step 101 by providing an environmental sensor means in the substrate processing system. The environmental sensor may be the environmental sensor of any of the above embodiments. For example, the environmental sensor can be disposed within any of the substrate handling and transporting system modules as shown in FIG. 1, which can include a FOUP handling module, a FOUP transport module, a substrate handling module, a substrate storage module, and a substrate transport module. Also, the environmental sensor can be disposed within the FOUP as shown in FIG. 2. The environmental sensor may be configured to measure environmental parameters of the substrate handling and transporting system modules, such as humidity, temperature, vibration, incident radiation, particle density, and chemical composition. The environmental sensor may be configured to transmit the measured environmental parameters to a controller, such the controller 50 as shown in FIG. 1.

At step 102, the method 100 may include determining threshold levels for the one or more environmental parameters. In some embodiments, the threshold levels may represent limits above which substrates within the substrate processing system may be damaged. For example, threshold level for a particle concentration such as oxygen may be set at 10 ppm [O₂]. Another example of a threshold level for humidity may be set at 5% relative humidity. The threshold levels may be determined by or communicated to a controller and may be stored in a memory within the controller.

At step 103, the method 100 may include determining one or more environmental parameters with the environmental sensor means. In some embodiments, the environmental parameters can be (directly) measured by one or more environmental sensors disposed in a part of the substrate processing system or a relevant module thereof. For example, an environmental sensor disposed within a stocker module can measure one or more environmental parameters of said stocker module and a second environmental sensor disposed within a substrate carousel module can measure one or more environmental parameters of said substrate carousel module. Alternatively, the environmental parameters can be calculated based on measurement by one or more environmental sensors disposed in another part of the substrate processing system or another module thereof that is environmentally connected. For example, if a first environmental sensor is disposed within a stocker module and a second environmental sensor is disposed within a substrate carousel module, then one or more environmental parameters for a substrate handling module disposed between said stocker module and said substrate carousel module can be calculated based on the one or more environmental parameters measured by said first and second environmental sensor. The calculations may be performed by a controller receiving the measured environmental parameters from one or more environmental sensors.

At step 103 the environmental sensor can be used to measure the environmental parameters in real time. Alternatively, the environmental sensor may measure the environmental parameters at certain times during transportation, handling, and processing of the substrates, such as between different modules of the substrate processing system or operations performed by said modules. The measurements may be stored in memory within the environmental sensor or the controller.

At step 104, the method 100 may include transmitting the one or more environmental parameters to a controller. In some embodiments, the transmission is wireless and can be accomplished with a wireless transmitter. The controller may include a wireless receiver and may store the received measurements. Alternatively, the transmission can be accomplished through a wired connection.

At step 105, the method 100 may include determining whether the one or more environmental parameters are within the threshold levels determined in step 102. This may include comparing, with the controller, the measured environmental parameters to the threshold levels.

In this way, the method 100 can split into two paths based on the outcome of the comparison performed by the controller. In particular, if the controller determines that the one or more measured environmental parameters are within the threshold levels, the method 100 may proceed directly to step 108 by transferring the substrate in the substrate processing system, for example, from one module to another module. However, if the controller determines that the one or more measured environmental parameters are not within the threshold levels, the method 100 may proceed to step 106 by indicating an alert instead.

At step 106, the method 100 may include indicating an alert that the environmental parameters are not within the threshold level. Step 106 can comprise displaying the alert, such as with a graphic or text, on a display device to inform an operator of the environmental problem. This display device may be similar to the display device 60 as shown in FIG. 1. This may help an operator to identify problems within the substrate processing system or any module thereof before transferring a substrate and in this way help to address the environmental problem as soon as possible.

At step 107, the method 100 may optionally include conducting an operation to correct the one or more environmental parameters. This can comprise taking the affected module or device of the substrate processing system offline and preventing transfer of substrates to and/or from said affected module or device in order to avoid contamination to other modules or devices. In some embodiments, step 107 may comprise purging (with nitrogen or other gases), flushing, scaling, renewing gas, reducing radiation, removing particles, reducing vibration, changing humidity, changing temperature and/or replacing mechanisms (for example, faulty seals) in the one or more modules or devices of the substrate processing system.

After step 107, the method 100 may optionally include determining if the one or more environmental parameters are within the threshold levels after conducting the operation of step 107. This may help to ensure that all problems are properly corrected and the substrate is ready for further transportation, handling and processing.

At step 108, the method 100 may include transferring the substrate in the substrate processing system, for example, from one module to another module. These modules can include any of the substrate handling and transporting system modules as shown in FIG. 1, such as a FOUP handling module, a FOUP transport module, a substrate handling module, a substrate storage module, and a substrate transport module. In one embodiment, the method 100 may further include transferring the substrate to a processing stage, for example, by transferring the substrate into the processing chamber. In this way, the relevant processing step can be safely initiated.

In an exemplary implementation within the scope of the present disclosure, the method 100 repeats after step 108, such that method flow goes back to step 101 and begins again. Iteration of the method 100 can be utilized to carry out ongoing (real time) monitoring of the environment within a substrate processing system.

As used herein, the terms “one embodiment” or “an embodiment” means that a particular feature, structure or characteristic described in connection with the embodiment is included in at least one embodiment of the present disclosure. Thus, appearances of the phrases “in some embodiments” in various places throughout this specification are not necessarily all referring to the same embodiments.

As used herein, the terms “comprising”, “comprises” and “comprised of” are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” said recited members, elements or method steps. The singular forms “a”, “an”, and “the” include both singular and plural referents unless the context clearly dictates otherwise.

As used herein, the terms “connected” or “coupled” reflect a functional relationship between the described objects or devices, that is, the terms indicate the described objects must be connected in a way to perform a designated function which may include a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” said value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all numbers and fractions subsumed within the respective ranges, as well as the recited endpoints. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

As used herein, the term “improved” with reference to the performance of devices or objects is a measure of a benefit obtained based on a comparison to similar devices or objects in the prior art. Furthermore, it is to be understood that the degree of improved performance may vary between disclosed embodiments and that no equality or consistency in the amount, degree, or realization of improved performance is to be assumed as universally applicable.

1. Substrate processing system having a controlled environment comprising:
one or more FOUPs configured to hold one or more substrates;
a substrate processing chamber configured to process the one or more substrates;
a substrate handling and transporting system configured to receive the one or more FOUPs and transfer the one or more substrates to and from the substrate processing chamber;
an environmental sensor means configured to measure one or more environmental parameters of the substrate handling and transporting system; and,
a controller communicatively coupled to the environmental sensor means, that is configured to
track one or more positions of the one or more substrates within the substrate handling and transporting system,
determine one or more environmental parameters of the substrate handling and transporting system,
determine whether the one or more environmental parameters are within threshold limits at the one or more positions of the one or more substrates, and
indicate an alert if the one or more environmental parameters are determined to not be within the threshold limits.

2. The system of the claim 1, wherein the substrate handling and transporting system comprises at least one of a FOUP handling module, a FOUP transport module, a substrate handling module, a substrate storage module, and a substrate transport module.

3. The system of claim 1, wherein the controller is configured to track the one or more positions of the one or more substrates based on an operation performed by the substrate handling and transporting system, wherein the operation comprises at least one of an unloading of the one or more substrates from the one or more FOUPs, a transferring of the one or more substrates within the substrate handling and transporting system, a storing of the one or more substrates, a loading of the one or more substrates into the substrate processing chamber, an unloading of the one or more substrates from the substrate processing chamber, a cooling of the one or more substrates, and a loading of the one or more substrates into one or more FOUPs.

4. The system of claim 1, wherein the controller is configured to issue an instruction to the substrate handling and transporting system to stop an operation by the substrate handling and transporting system if the one or more environmental parameters are determined to not be within the threshold limits, wherein the operation comprises at least one of stopping an unloading of the one or more substrates from the one or more FOUPs, stopping a transfer of the one or more substrates within the substrate handling and transporting system, stopping a loading of the one or more substrates into the substrate processing chamber, stopping an unloading of the one or more substrates from the substrate processing chamber, and stopping a loading of the one or more substrates into one or more FOUPs.

5. The system of claim 1, wherein the controller is configured to determine one or more processing conditions based on the one or more environmental parameters, and to issue an instruction to the substrate processing chamber to process the one or more substrates based on said processing conditions.

6. The system of claim 1, comprising one or more environmental support devices configured to support the controlled environment of the substrate processing system, and wherein the controller is configured to issue an instruction to the one or more environmental support devices to correct the environment if the one or more environmental parameters are determined to not be within the threshold limits, wherein the correction comprises at least one of purging, sealing, flushing, renewing gas, reducing radiation, reducing vibration, removing particles, changing humidity, and changing a temperature.

7. The system of claim 1, wherein the environmental sensor means comprises one or more environmental sensors disposed within the substrate handling and transporting system, and wherein the controller is configured to determine the one or more environmental parameters of the substrate handling and transporting system based on measurement from said environmental sensors.

8. The system of claim 1, wherein the environmental sensor means is configured to measure at least one of a particle concentration, chemical composition, humidity, temperature, vibration, and incident radiation.

9. The system of claim 1, wherein the controller is configured to determine whether the one or more environmental parameters are within threshold limits at particular times based on an operation performed by the substrate processing system, wherein the operation comprises at least one of an unloading of the one or more substrates from the one or more FOUPs, a transferring of the one or more substrates within the substrate handling and transporting system, a storing of the one or more substrates, a loading of the one or more substrates into the substrate processing chamber, an unloading of the one or more substrates from the substrate processing chamber, a cooling of the one or more substrates, and a loading of the one or more substrates into one or more FOUPs.

10. The system of claim 1, wherein the environmental sensor means further comprises one or more environmental sensors disposed within the one or more FOUPs, and wherein the controller is configured to determine one or more environmental parameters of the one or more FOUPs based on measurement from said environmental sensors.

11. The system of claim 1, wherein the environmental sensor means further comprises one or more environmental sensors disposed within the substrate processing chamber, and wherein the controller is configured to determine one or more environmental parameters of the substrate processing chamber based on measurement from said environmental sensors.

12. Apparatus for monitoring a controlled environment of a substrate handling and transporting system configured to receive one or more front opening universal pods (FOUPs) holding one or more substrates and to transfer the one or more substrates to and from a substrate processing chamber, the apparatus comprising:
an environmental sensor means configured to measure one or more environmental parameters of the substrate handling and transporting system; and,
a controller communicatively coupled to the environmental sensor means, that is configured to
track one or more positions of the one or more substrates within the substrate handling and transporting system,
determine one or more environmental parameters of the substrate handling and transporting system,
determine whether the one or more environmental parameters are within threshold limits at the one or more positions of the one or more substrates, and
indicate an alert if the one or more environmental parameters are determined to not be within the threshold limits.

13. Method for monitoring of a controlled environment within a substrate handling and transporting system configured to receive one or more front opening universal pods (FOUPs) holding one or more substrates and to transfer the one or more substrates to and from a substrate processing chamber; the method comprising the steps of:
tracking one or more positions of the one or more substrates within the substrate handling and transporting system;
determining one or more environmental parameters of the substrate handling and transporting system at the one or more positions of the one or more substrates; and
determining whether the one or more environmental parameters are within threshold limits and indicating an alert if the one or more environmental parameters are determined to not be within the threshold limits.

14. The method of claim 13, wherein the substrate handling and transporting system comprises at least one of a FOUP handling module, a FOUP transport module, a substrate handling module, a substrate storage module, and a substrate transport module.

15. The method of claim 13, wherein the one or more positions of the one or more substrates are tracked based on an operation performed by the substrate handling and transporting system, wherein the operation comprises at least one of an unloading of the one or more substrates from the one or more FOUPs, a transferring of the one or more substrates within the substrate handling and transporting system, a storing of the one or more substrates, a loading of the one or more substrates into the substrate processing chamber, an unloading of the one or more substrates from the substrate processing chamber, a cooling of the one or more substrates, and a loading of the one or more substrates into one or more FOUPs.

16. The method of claim 13, further comprising, determining one or more environmental parameters of the substrate handling and transporting system at one or more future positions of the one or more substrates; and determining whether said one or more environmental parameters are within threshold limits.

17. The method claim 13, further comprising, stopping an operation by the substrate handling and transporting system if the one or more environmental parameters are determined to not be within the threshold limits, wherein the operation comprises at least one of stopping an unloading of the one or more substrates from the one or more FOUPs, stopping a transferring of the one or more substrates within the substrate handling and transporting system, stopping a loading of the one or more substrates into the substrate processing chamber, stopping an unloading of the one or more substrates from the substrate processing chamber, and stopping a loading of the one or more substrates into one or more FOUPs.

18. The method of claim 13, further comprising, determining one or more processing conditions based on the one or more environmental parameters, and processing the one or more substrates within the substrate processing chamber based on said processing conditions.

19. The method of claim 13, further comprising, correcting the environment if the one or more environmental parameters are determined to not be within the threshold limits, wherein the correcting comprises at least one of purging, sealing, flushing, renewing gas, reducing radiation, reducing vibration, removing particles, changing humidity, and changing a temperature.

20. The method of claim 13, wherein the step of determining whether one or more environmental parameters are within threshold limits takes place at particular times based on an operation performed by the substrate handling and transporting system, wherein the operation comprises at least one of an unloading of the one or more substrates from the one or more FOUPs, a transferring of the one or more substrates within the substrate handling and transporting system, a storing of the one or more substrates, a loading of the one or more substrates into the substrate processing chamber, an unloading of the one or more substrates from the substrate processing chamber, a cooling of the one or more substrates, and a loading of the one or more substrates into one or more FOUPs.
